(19) United States
(12) Patent Application Publication
(10) Pub. No.: US 2003/0091125 A1
(43) Pub. Date: May 15, 2003

(54) System and method for limiting and filtering a signal

(76) Inventors: Jack P. Glas, Basking Ridge, NJ (US); Vladimir I. Prodanov, New Providence, NJ (US)

Correspondence Address: Daniel J. Santos, Esq., Thomas, Kayden, Horstemeyer & Risley, L.L.P., Suite 1750, 100 Galleria Parkway, Atlanta, GA, 30339, US

(21) Appl. No.: 10/012,997

(22) Filed: Nov. 13, 2001

(51) Int. Cl. H03K 9/00

(52) U.S. Cl. 375/316

(57) ABSTRACT

A system and method for limiting and filtering a combined signal is provided. An embodiment of the system comprises at least one soft limiter and filter that soft limits and filters the combined signal to output a soft limited and filtered signal. An embodiment of the method comprises soft limiting and filtering the combined signal to output the soft limited and filtered signal.

### TECHNICAL FIELD OF THE INVENTION

The present invention is generally related to the field of communications and, more particularly, to a system and method for limiting and filtering a signal.

### BACKGROUND OF THE INVENTION

FIG. 1 is a block diagram of a typical known receiver 110. The receiver 110 comprises a low noise amplifier 112 (LNA), a mixer component 114, an amplifier 116, a filter 118, a hard limiter 120, an analog-to-digital converter (ADC) 122, a processor 124, and a detector 126. The mixer component 114 typically comprises a first mixer (not shown) and a second mixer (not shown). The mixer component 114 may comprise any number of mixers, as is generally understood by people skilled in the art. The tasks performed by each of these components, although generally known in the art, will be described below in detail.

A line 132 that is the input to the LNA 112 couples the LNA 112 with an antenna (not shown). A line 134 couples the LNA 112 to the mixer component 114. A line 136 couples the mixer component 114 to the amplifier 116. A line 138 couples the amplifier 116 to the filter 118. A feedback loop in the receiver 110 couples a detector 126 to the output of the filter 118 and to the input of the amplifier 116. The feedback loop also comprises a line 146 that connects the filter 118 to the detector 126, and a line 144 that connects the detector 126 to the amplifier 116. The purpose for this feedback loop will be described below in detail.

Line 140 couples the output of the filter 118 to the input of the hard limiter 120, and a line 148 couples the output of the hard limiter 120 to the ADC 122, which converts the output of the hard limiter 120 into a digital signal that can be utilized by the processor 124. A line 150 couples the ADC 122 to the processor 124. A line 152 couples the processor 124 to a receive data end point (not shown), which may be, for example, some type of computer.

The LNA 112 amplifies a signal that the receiver 110 receives. The receiver 110 may receive a radio frequency (RF) signal having any modulation format known to people having ordinary skill in the art. Different types of modulation formats include amplitude modulation (AM), phase modulation (PM), frequency modulation (FM), pulse amplitude modulation (PAM), carrierless amplitude/phase modulation (CAP), discrete multitone modulation (DMT), discrete wavelet multitone modulation (DWMT), quadrature amplitude modulation (QAM), and angular modulation. Angular modulation, as known to people having ordinary skill in the art, is modulation of frequency, phase, or both frequency and phase. The LNA 112 then outputs an amplified signal to the mixer component 114.

The line 134 that couples the output of the LNA 112 to the mixer component 114 typically bifurcates into two signal-carrying wires (not shown), where the first of the two wires is coupled to the input of the aforementioned first mixer and the second of the two wires is coupled to the input of the second mixer. The lines 136, 138, 140 and possibly 148 and 150 comprise two independent signal-carrying wires (not shown). The first mixer receives the amplified signal and is being driven by an in-phase local oscillator (LO) signal. The second mixer also receives the amplified signal but is driven by a quadrature-phase LO signal. The signals produced at the output of the mixers are frequency shifted versions of the amplified signal. This frequency shift translates certain frequencies of the amplified signal to non-zero intermediate frequencies (IF). This type of shifting of certain frequencies of the amplified signal down to non-zero intermediate frequencies is typical and is generally known to persons skilled in the art. The mixer component 114 may also further amplify the amplified signal received from the LNA 112.

The amplifier 116 receives a non-zero IF signal that is output from the mixer component 114, and amplifies the signal such that an amplified non-zero IF signal is output from the amplifier 116. The filter 118 filters out undesired or interference signals, such as blockers, so that only a desired signal is output from the filter 118. A blocker is a signal intended for receivers other than the receiver that actually receives the blocker. The desired signal is a signal that comprises data to be extracted by the intended receiver. The strength of the desired signal may vary as much as 60-70 dB. Without the use of the filter 118, a blocker can be much stronger than the desired signal and can completely block, or interfere with, the desired signal that is input to the hard limiter 120. Typically, the filter 118 is designed to pass only the desired signal.

The hard limiter 120 hard limits the desired signal by quantizing the desired signal to two levels to simplify handling of the desired signal. The hard limiter 120 thereby outputs a two-level signal. For instance, if portions of the desired signal have a value that is not greater than zero, the hard limiter 120 simply outputs values of zero for these signal portions. If portions of the desired signal have a value that is greater than zero, the hard limiter 120 simply outputs a constant non-zero value for these portions of the signal. The ADC 122 receives the two-level signal and converts the signal from an analog format to a digital format, and outputs a digital signal that can be utilized by the processor 124.

The processor 124 then demodulates the digital signal to extract data, such as bits, from the digital signal and outputs the data on line 152 to the receive data end point (not shown). As an example, the processor 124 can demodulate the digital signal as follows. The processor 124 counts distances between consecutive edges of the digital signal and assigns a digital value to each portion of the digital signal between the two consecutive edges. The digital value is assigned based on the distance between the consecutive edges. Edges are portions of the digital signal when the digital signal transitions from the value of zero to the constant value, and vice versa. The processor 124 also performs other functions such as, for example, data synchronization and data detection.

One of the disadvantages of the receiver of the type shown in FIG. 1 is the need for the aforementioned feedback loop between the output of the filter 118 to the input of the detector 126, and from the output of the detector 126 to the input of the amplifier 116. The detector 126 provides automatic gain control by measuring the strength of a signal that is output from the filter 118 and changing the gain of the amplifier 116 so that the filter 118 does not operate in a non-linear mode. For example, if the strength of a signal received by the filter 118 is high, the detector 126 reduces the gain of the amplifier 116 to protect the filter 118. Alternatively, if the strength of the signal output from the filter is low, the detector 126 increases the gain of the amplifier 116. The amplifier 116 generally has a large range of adjustable gain to accommodate varying the strength of a signal that is output from the mixer component 114, over the large range. Hence, the detector 126 is needed to measure the strength of the signal that the filter 118 outputs, to prevent the filter 118 from being operated in the non-linear mode.

The automatic gain control can, alternatively, be provided by an automatic gain control algorithm that is executed by the processor 124, which is typically a digital signal processor (DSP). The processor 124 would then provide an automatic gain control value to the amplifier 116.

Regardless of the manner in which automatic gain control is provided, the requirement of providing the automatic gain control increases the financial costs of configuring and implementing the receiver 110. The increased costs are typically due to the costs of implementing the amplifier 116 with the large range of adjustable gain and the costs of the detector 126 that measures the strength of the signal that the filter 118 outputs. A further disadvantage is that changing the gain of the amplifier 116 introduces a transient in the receiver 110, which temporarily prevents the receiver 110 from receiving a signal, thereby rendering the receiver 110 inoperative immediately after each gain adjustment. The transient is generally referred to as blanking time. The duration of the blanking time is considerably increased by the filter 118 since the filter 118 contains reactive elements such as resistors and capacitors. The blanking time seriously affects the performance of the receiver 110. For instance, the blanking time results in an increased inaccuracy of the automatic gain control, an increased inaccuracy in data synchronization by the receiver 110, and an increased chance of not detecting a valid packet of data. Although specific algorithms are sometimes implemented to compensate for the loss of the performance of the receiver 110, configuring and implementing the receiver 110 to perform these algorithms is also costly.

Accordingly, a need exists for a receiver that overcomes the above-mentioned high costs and performance deficiencies associated with utilizing automatic gain control in a receiver, such as the receiver 110.

### SUMMARY OF THE INVENTION

The present invention provides a system and method for limiting and filtering a combined signal without the need for detecting the strength of a signal that is output from a filter and for providing automatic gain control to an amplifier for the purpose of controlling the strength of a signal that the filter filters.

Briefly described, in architecture, one embodiment of the system, among others, can be implemented as follows: at least one soft limiter and filter that soft limits and filters a combined signal to output a soft limited and filtered signal.

The present invention can also be viewed as providing methods for limiting and filtering a signal. In this regard, one embodiment of such a method, among others, can be broadly summarized by the following step: soft limiting and filtering the combined signal to output the soft limited and filtered signal.

The present invention can be comprised in a receiver. The receiver does not comprise a detector and an amplifier with a large range of adjustable gain, or alternatively a DSP implementing the automatic gain control algorithm since there is no need to provide the automatic gain control. The receiver comprises a soft limiter that soft limits a signal to prevent a filter that the receiver comprises, from being operated in a non-linear mode.

Other features and advantages of the present invention will be or become apparent to one with skill in the art upon examination of the following drawings and detailed description. It is intended that all such additional features and advantages be included within this description, be within the scope of the present invention, and be protected by the accompanying claims.

### BRIEF DESCRIPTION OF THE DRAWINGS

FIG. 1 is a block diagram of a typical known receiver.

FIG. 2 is a block diagram of an example embodiment of a receiver of the present invention.

FIG. 3 is an internal block diagram of a chain that is comprised by the receiver of FIG. 2.

FIG. 4 is an internal block diagram of an example embodiment of a soft limiter and filter of the chain shown in FIG. 3.

FIG. 5A is a circuit diagram of an example embodiment of a soft limiter of the soft limiter and filter shown in FIG. 4.

FIG. 5B is a graph of current-to-voltage characteristics of the soft limiter of FIG. 5A.

FIG. 6A is a circuit diagram of another example embodiment of the soft limiter of the soft limiter and filter shown in FIG. 4.

FIG. 6B is a graph of voltage-to-current characteristics of the soft limiter of FIG. 6A.

FIG. 7 is an internal block diagram of another example embodiment of the chain of the receiver of FIG. 2.

FIG. 8A is a circuit diagram of a preferred embodiment of a soft limiter and filter of the chain shown in FIG. 7.

FIG. 8B is a circuit diagram of another example embodiment of the soft limiter and filter of the chain of FIG. 7.

FIG. 9A is a graph of a signal and a blocker that are input to the soft limiter of FIG. 4 and to soft limiter portions of FIGS. 8A and 8B, respectively.

FIG. 9B is a graph of a signal and a blocker that are output from the soft limiter of FIG. 4, and from the soft limiter portions of FIGS. 8A and 8B, respectively.

### DETAILED DESCRIPTION OF THE INVENTION

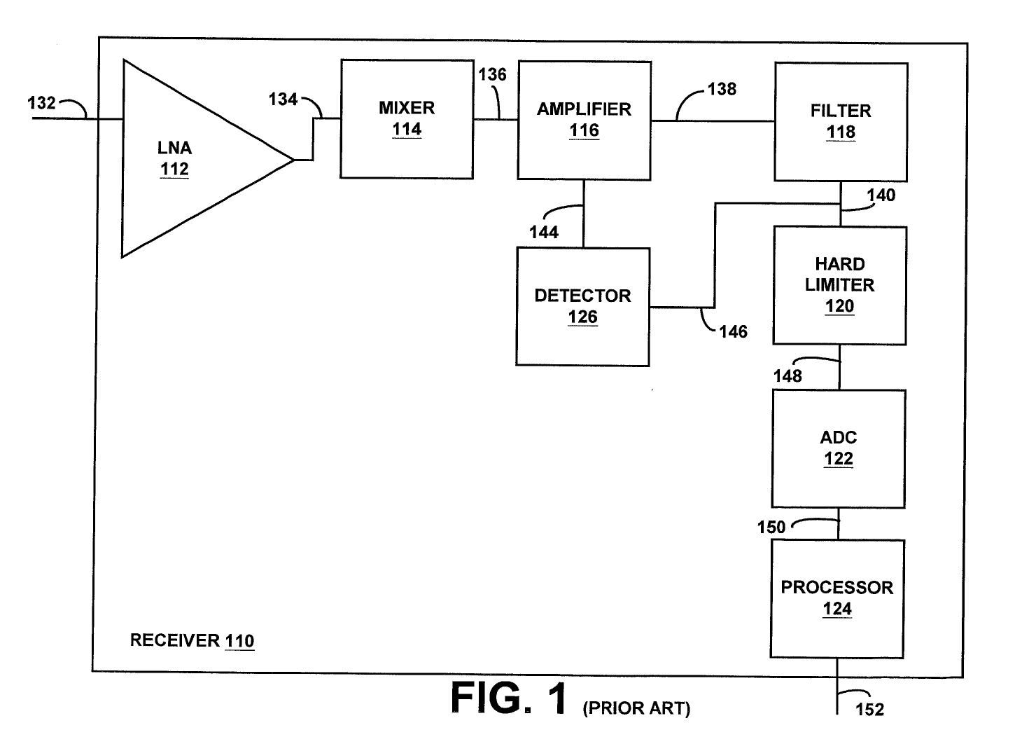

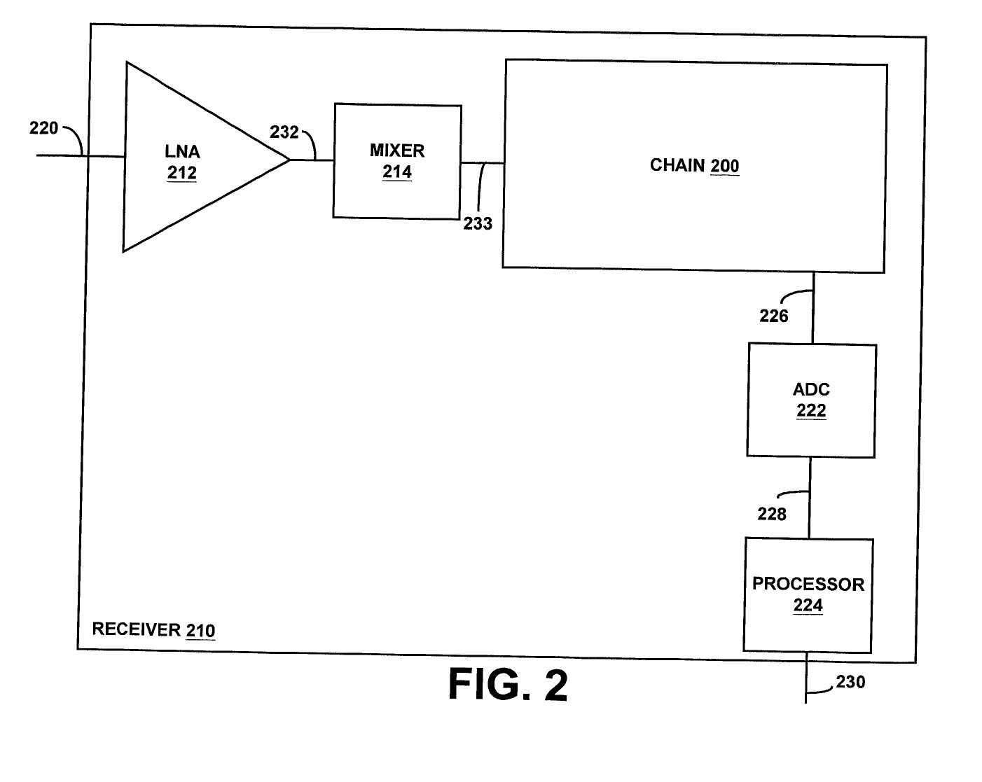

FIG. 2 is a block diagram of an example embodiment of a receiver 210, in accordance with the present invention. The receiver 210 comprises the LNA 212, which may be identical to the LNA 112 shown in FIG. 1, a mixer component 214, which may be identical to the mixer component 114 shown in FIG. 1, a chain 200, an ADC 222, which may be identical to ADC 122 shown in FIG. 1, and a processor 224, which may be identical to the processor 124 shown in FIG. 1. A line 220 couples an antenna (not shown) to the LNA 212. A line 232 couples the LNA 212 to the mixer component 214. A line 233 couples the mixer component 214 to a chain 200, and a line 226 couples the chain 200 to the ADC 222. A line 228 couples the ADC 222 to the processor 224, which is coupled by a line 230 to the receive data end point (not shown) that was described while describing FIG. 1.

The LNA 212 receives an RF signal preferably having angular modulation, and performs the same functions as those described above with reference to FIG. 1. The LNA 212 then outputs an amplified signal to mixer component 214. The LNA 112 may, alternatively, receive an RF signal having any modulation format such as those described above with reference to FIG. 1. The mixer component 214 receives the amplified signal, and performs the same functions as those described above with reference to FIG. 1, and outputs a non-zero IF signal. The chain 200 receives the non-zero IF signal and interference signals, such as a blocker. The non-zero IF signal and the blocker are collectively referred to as a combined signal. The chain 200 filters and limits the combined signal. The chain 200 outputs a limited filtered signal. The ADC 222 receives the limited filtered signal, performs the same functions described above with reference to FIG. 1, and outputs a digital signal to the processor 224, which performs the same functions on the digital signal as those described above with reference to FIG. 1. The processor 224 then outputs data to the receive data end point via line 230.

The financial costs of configuring and implementing the receiver 210 of the present invention are lower than the financial costs of configuring and implementing the receiver 110 (FIG. 1) because the receiver 210 need not provide the automatic gain control, and thus does not require the detector 126 and amplifier 116 of the receiver 110 of FIG. 1. As described in more detail below, the chain 200 comprises a soft-limiter that eliminates the possibility of a signal being strong enough to force a filter to operate in a non-linear mode. The chain 200, therefore, need not comprise the amplifier 116 and the detector 126 of FIG. 1 to provide the automatic gain control. Additionally, the chain 200 need not comprise a DSP that executes an automatic gain control algorithm for controlling an amplifier, such as the amplifier 116 (FIG. 1), having a large range adjustable of adjustable gain. Hence, the financial costs of configuring and implementing the receiver 210 are lower than those associated with configuring and implementing the receiver 110. Additionally, performance problems associated with transient modes caused by changes in the gain of an amplifier, such as the amplifier 116 (FIG. 1), are obviated.

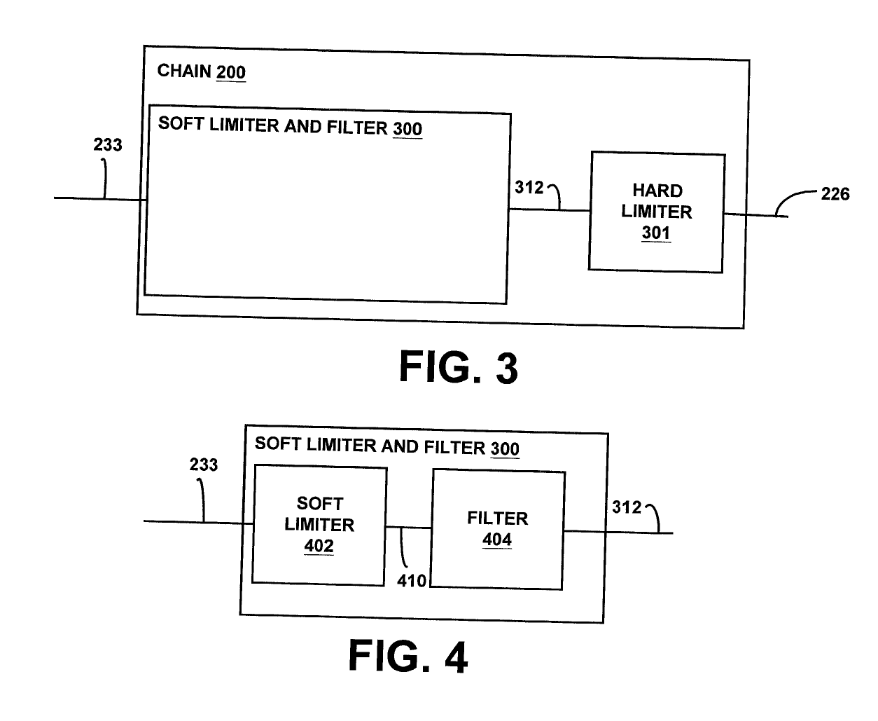

FIG. 3 is an internal block diagram of an example embodiment of the chain 200 of FIG. 2. The chain 200 comprises a soft limiter and filter, designated by numeral 300, and a hard limiter 301, such as the hard limiter 120 described above with reference to FIG. 1. A line 312 couples the soft limiter and filter 300 to the hard limiter 301. The soft limiter and filter 300 soft limits and filters the combined signal. The soft limiter and filter 300 outputs a soft limited and filtered signal over the line 312 to the hard limiter 301. When the combined signal comprises only a blocker that is input to a soft limiter that the soft limiter and filter 300 comprises, the blocker passes through a linear region of the soft limiter and is not limited. Otherwise, the soft limiter soft limits the combined signal when the combined signal comprises both the non-zero IF signal and the blocker.

The hard limiter 301 performs the same functions on the soft limited and filtered signal as those performed by the hard limiter 120 on a filtered signal as described above with reference to FIG. 1. The hard limiter 301 then outputs the limited filtered signal, which has either a value of zero or a non-zero constant value, as discussed above with reference to FIG. 1. The signal output from the hard limiter 301 is then input to the ADC 222 (FIG. 2), which converts the limited filtered signal from analog to a digital signal in the manner discussed above while describing FIG. 1, so that the digital signal can be utilized by the processor 224.

FIG. 4 is an internal block diagram of an example embodiment of the soft limiter and filter 300 shown in FIG. 3. The block diagram shows a connection 410 of a soft limiter 402 to a filter 404. Any suitable filter can be used for this purpose, such as the filter 118 described above with reference to FIG. 1. The soft limiter and filter 300 can comprise any number of soft limiters and any number of filters. For instance, additional soft limiters and additional filters can be coupled between the filter 404 and the hard limiter 301 (FIG. 3).

The soft limiter 402 soft limits the combined signal. The soft limiter 402 outputs a soft limited signal that cannot place the filter 404 in a nonlinear mode. The filter 404 filters out the blocker and outputs the soft limited and filtered signal via the line 312 to the hard limiter 301 (FIG. 3) of the chain 200 (FIG. 3). As stated above, the hard limiter 301 outputs the limited filtered signal, which is essentially either a value of zero, or a non-zero constant value, which the ADC 222 (FIG. 2) then converts into a digital signal.

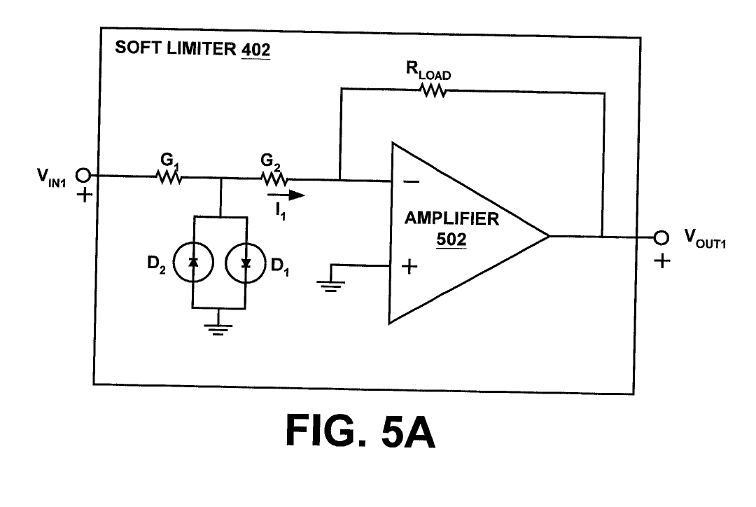

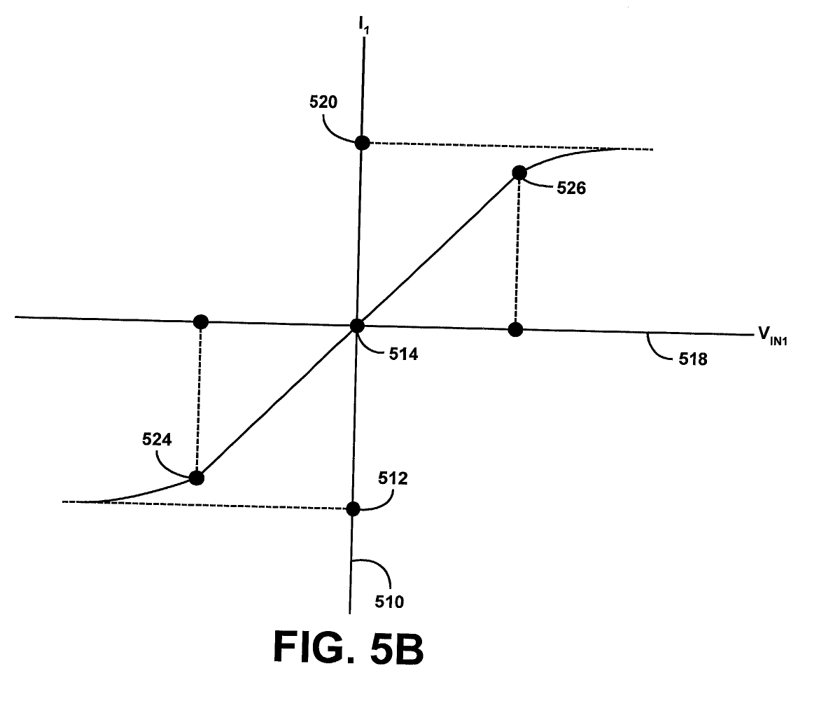

FIG. 5A is a circuit diagram of an example embodiment of the soft limiter 402 shown in FIG. 4. The manner in which this circuit operates will be discussed with reference to FIGS. 5A and 5B. FIG. 5B is a graph of current-to-voltage characteristics of the soft limiter 402 of FIG. 5A. An axis 518 represents a range of values of a voltage V_{IN1} from negative to positive infinity. An axis 510 represents a range of values of a current I₁ from negative to positive infinity. A point 514 is a centerpoint where values of both V_{IN1} and I₁ are zero. The relevance of this graph to the operation of the soft limiter 402 shown in FIG. 5A will become apparent from the discussion of FIG. 5A.

The soft limiter 402 shown in FIG. 5A comprises a resistor with conductance G₁, referred to herein as a resistor G₁, a resistor with conductance G₂, referred to herein as a resistor G₂, diodes D₁ and D₂, a resistor R_{LOAD}, and an amplifier 502. The amplifier 502 of the soft limiter 402 is preferably an operational amplifier. However, any other amplifier that is suited for the purpose for which it is used in the soft limiter 402 may be used. The resistor G₁ is coupled to the diodes D₁ and the D₂. The resistor G₁ is also coupled to the resistor G₂. The resistor G₂ is coupled to the resistor R_{LOAD}, and to an inverting output of the amplifier 502. The current I₁ is a current flowing through the resistor G₂. V_{OUT1} is voltage at the output of the amplifier 502. The resistor G₁ is coupled to the input voltage V_{IN1}. The diodes D₁ and D₂, and a non-inverting input terminal of the amplifier 502, are coupled to a ground.

When V_{IN1} is between certain known values, both the diodes D₁ and D₂ are off, and there is a linear relationship between the current I₁ and the voltage V_{IN1}. The linear relationship between the current I₁ and V_{IN1} is characterized by the equation:

V_{IN1}=C₁I₁ Equation 1

where C₁ is a constant. The linear relationship is shown by a line connecting points 524 and 526 in FIG. 5B. The soft limiter 402 soft limits a signal input to the soft limiter 402 by soft limiting the current I₁ between two values, for instance, −V_{BE(ON)}G₂ and V_{BE(ON)}G₂. V_{BE(ON)}, which is usually 0.7 V, is voltage across the diode D₁. Alternatively, V_{BE(ON)} can be 0.5 V or any other value, depending on the diode used, as will be understood by those skilled in the art. When the voltage V_{IN1} is large enough to turn on the diode D₁, the voltage across the diode D₁ is V_{BE(ON)}, and the current I₁ saturates to the constant value of V_{BE(ON)}G₂. The value of V_{BE(ON)}G₂ corresponds to a point 520 in FIG. 5B. At this time, the diode D₂ (FIG. 5A) is off.

When the voltage V_{IN1} is negative enough to turn on the diode D₂, the voltage across the diode D₁ is −V_{BE(ON)}, and the current I₁ saturates to the constant value of −V_{BE(ON)}G₂, which corresponds to point 512 in FIG. 5B. At this time, the diode D₁ is off.

The significance of these events can be seen from the relationship between the voltage V_{OUT1} and the current I₁ as given by Equations 2, 3 and 4 as follows:

V_{OUT1}=−R_{LOAD}I₁ Equation 2

V_{OUT1} is a constant if the current I₁ is a constant. Hence, when the current I₁ saturates to the constant value of V_{BE(ON)}G₂,

V_{OUT1}=−R_{LOAD}V_{BE(ON)}G₂ Equation 3

Alternatively, when the current I₁ saturates to the constant value of −V_{BE(ON)}G₂,

V_{OUT1}=R_{LOAD}V_{BE(ON)}G₂ Equation 4

Therefore, V_{OUT1} can never exceed these boundaries, and thus the filter 404 (FIG. 4) cannot be driven into a nonlinear mode by the output of the soft limiter 402.

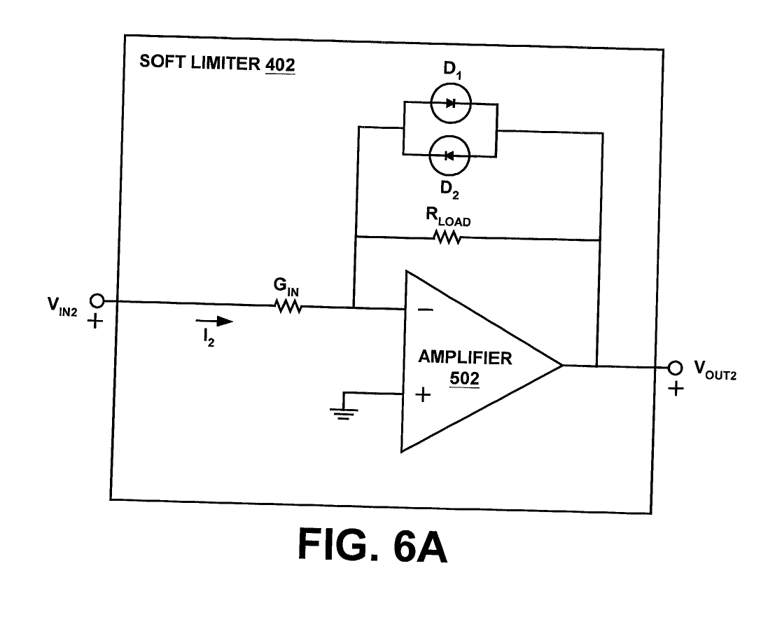

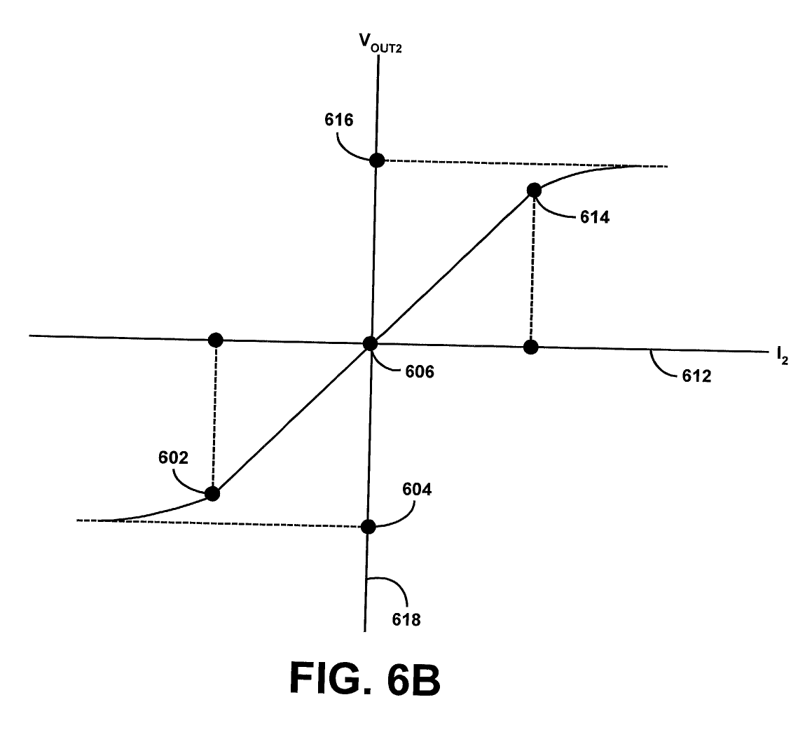

FIG. 6A is a circuit diagram of another example embodiment of the soft limiter 402 of FIG. 4. FIG. 6B is a graph of voltage-to-current characteristics of the soft limiter 402 of FIG. 6A. With reference to FIG. 6B, axis 612 represents a range of values, from negative to positive infinity, of a current I₂. An axis 618 represents a range of values, from negative to positive infinity, of a voltage V_{OUT2}. A point 606 is a centerpoint, where values of both V_{OUT2} and I₂ are zero. The soft limiter 402 of the example embodiment of FIG. 6A comprises a resistor with conductance G_{IN}, referred to herein as a resistor G_{IN}, the diodes D₁ and D₂ (FIG. 5A), the resistor R_{LOAD} (FIG. 5A), and the amplifier 502 (FIG. 5A).

The resistor G_{IN} receives an input voltage V_{IN2}. The resistor G_{IN} is coupled to the resistor R_{LOAD}, the diodes D₁ and D₂, and the inverting input of the amplifier 502. The diodes D₁ and D₂ are coupled in parallel to the resistor R_{LOAD}. Non-inverting input of the amplifier 502 is grounded. V_{OUT2} is the output voltage of the amplifier 502. I₂ is the current flowing through the resistor G_{IN}. When V_{IN2} is between certain values, both the diodes D₁ and D₂ are off, and there is a linear relationship between the voltage V_{OUT2} and I₂. The linear relationship, which is shown by a line connecting points 602 and 614 in FIG. 6B, is expressed as:

V_{OUT2}=C₂I₂ Equation 5

where C₂ is a constant.

The soft limiter 402 of the embodiment of FIG. 6A soft limits a signal input to the soft limiter 402 by limiting the signal between the two values −V_{BE(ON)} and V_{BE(ON)}. When the voltage V_{IN2} is large enough to turn on the diode D₁, the voltage across the diode D₁ is V_{BE(ON)}, and the voltage V_{OUT2} saturates to the value of −V_{BE(ON)}. The value of −V_{BE(ON)} corresponds to point 604 in FIG. 6B. At this time, the diode D₂ is off. When the voltage V_{IN2} is small enough to turn on the diode D₂, the voltage across the diode D₁ is −V_{BE(ON)}, and the voltage V_{OUT2} saturates to the constant value of V_{BE(ON)}. The value of V_{BE(ON)} corresponds to point 616 in FIG. 6B. At this time, the diode D₁ is off. The relationship between the voltage V_{IN2} and the current I₂ is given by

I₂=G_{IN}V_{IN2} Equation 6

Therefore, V_{OUT2} is limited in accordance with Equations 5 and 6 to thereby prevent the filter 404 (FIG. 4) from operating in a nonlinear mode.

It should be noted that the soft limiter of FIGS. 4, 5A and 6A provides a limited output, which becomes the input to the filter 404 (FIG. 4). The output is an alternating current (AC) signal that differs from an output of a hard limiter, which is either a value of zero or a non-zero constant value.

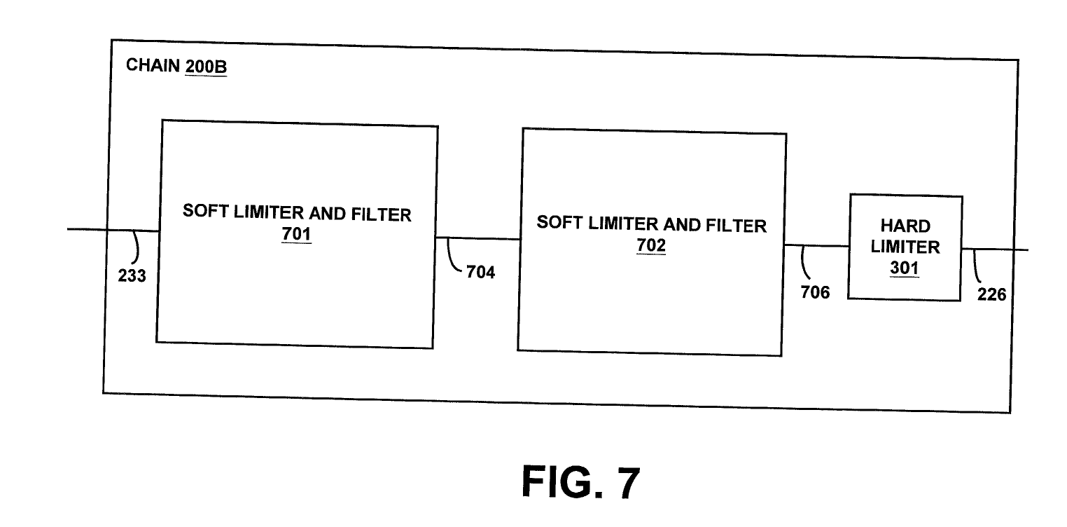

FIG. 7 is an internal block diagram of an alternative embodiment of the chain 200 of FIG. 2. The embodiment is referred to as a chain 200B. The chain 200B comprises two soft limiter and filters 701 and 702, and the hard limiter 301 (FIG. 3). A line 704 couples the soft limiter and filter 701 to the soft limiter and filter 701, and a line 706 couples the soft limiter and filter 702 to the hard limiter 301 (FIG. 3). The chain 200B may comprise only one soft limiter and filter, or may comprise any number of soft limiters and filters. Having multiple soft limiter and filters helps lower input-referred noise of the chain 200B. Input-referred noise, as known to people having ordinary skill in the art, is an equivalent noise at the input of the chain 200B, when all the noise of the chain 200B is presumed to be at the input of the soft limiter and filter 701. Gain inside the chain 200B can be redistributed since a soft limiter that each of the soft limiter and filters 701 and 702 comprise, soft limits a signal that is input to each of the soft limiter and filters 701 and 701. Redistributing gain allows for minimization of the input-referred noise of a filter that each of the soft limiters, comprise. Such a large gain redistribution generally cannot be done in a receiver such as the receiver 110 (FIG. 1) since the receiver 110 (FIG. 1) does not soft limit a signal that is input to the receiver 110 (FIG. 1).

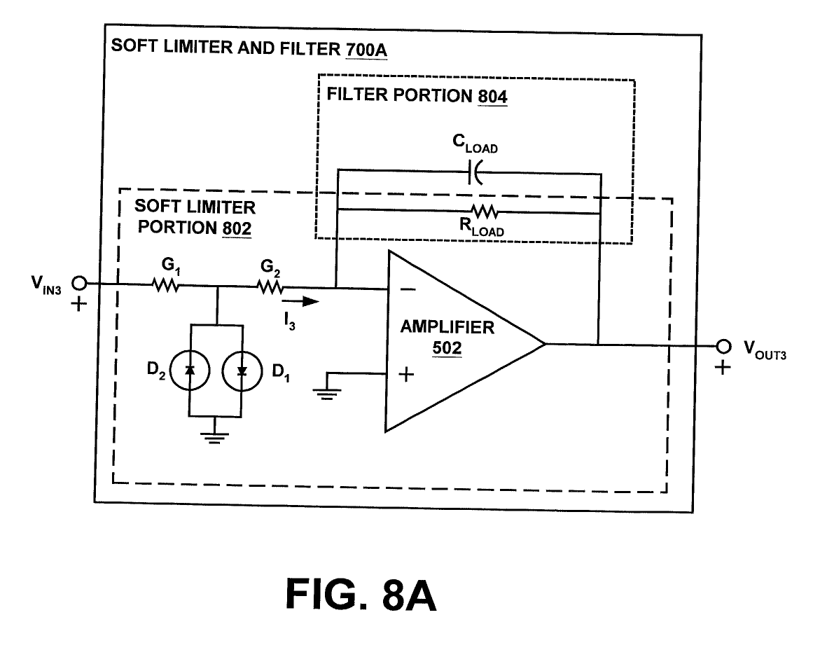

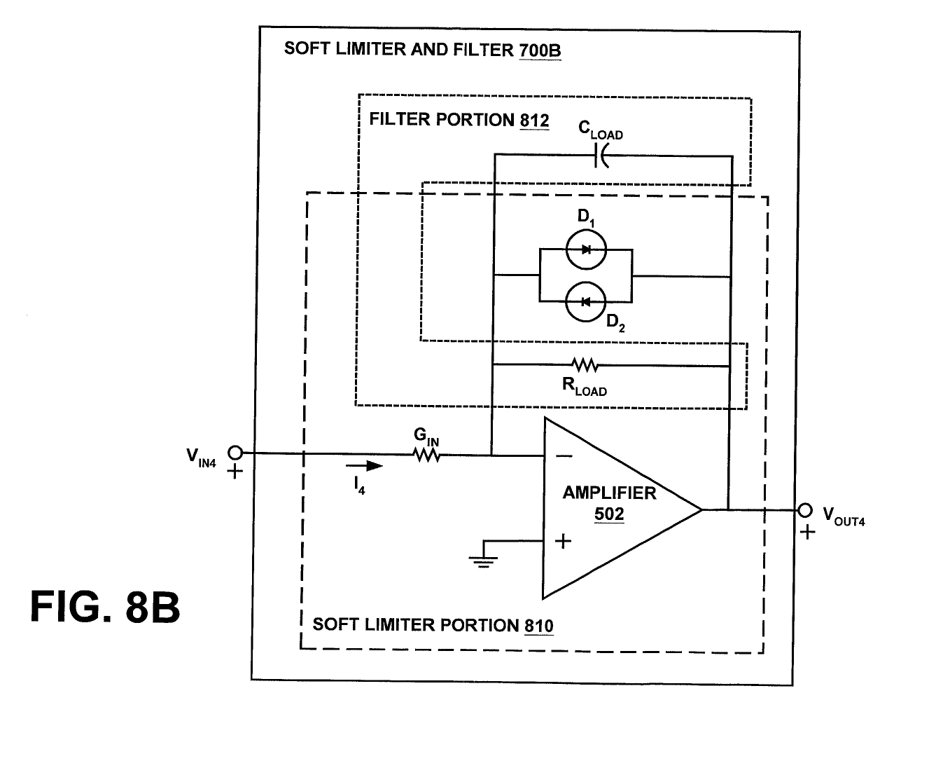

FIG. 8A is a circuit diagram of a preferred embodiment of each of the soft limiter and filters 701 and 702 of FIG. 7 of the present invention. This embodiment of each of the soft limiter and filters 701 and 702 of the present invention is labeled with the numeral 700A. The soft limiter and filter 700A comprises a single circuit. The soft limiter and filter 700A comprises a soft limiter portion 802, and a filter portion 804. The soft limiter portion 802 comprises the same components as comprised in the soft limiter 402 of FIG. 5A. The components in the soft limiter portion 802 are connected in the same manner as they are connected in the soft limiter 402 of FIG. 5A. The filter portion 804 comprises a capacitor C_{LOAD}, and the resistor R_{LOAD}. The capacitor C_{LOAD} is coupled in parallel to the resistor R_{LOAD}. The resistor G₁ is coupled to an input voltage V_{IN3} of the circuit. V_{OUT3} is an output voltage of the amplifier 502, and I₃ is a current through the resistor G₂.

The soft limiter portion 802 soft limits as follows. When V_{IN3} is between certain values, both the diodes D₁ and D₂ are off, and there is a linear relationship between the current I₃ and the voltage V_{IN3}. The linear relationship can be expressed as:

V_{IN3}=C₃I₃ Equation 7

where C₃ is a constant. The soft limiter portion 802 soft limits a signal that is input to the soft limiter and filter 700A, by limiting the signal between two values, −V_{BE(ON)}G₂ and V_{BE(ON)}G₂. When the voltage V_{IN3} is large enough to turn on the diode D₁, the voltage across the diode D₁ is V_{BE(ON)}, and the current I₃ saturates to the constant value of V_{BE(ON)}G₂. The diode D₂ is off at this time. When the voltage V_{IN3} is small enough to turn on the diode D₂, the voltage across the diode D₁ is −V_{BE(ON)}, and the current I₃ saturates to the constant value of −V_{BE(ON)}G₂. The diode D₁ is off at this time.

The capacitor C_{LOAD} and the resistor R_{LOAD} form a frequency-dependent network that filters the signal. Hence, the soft limiter portion 802 first soft limits the signal, and then the filter portion 804 filters the signal.

FIG. 8B is a circuit diagram of an alternative embodiment of the each of the soft limiter and filters 701 and 702 of FIG. 7 of the present invention. The embodiment is labeled with a numeral 700B. The soft limiter and filter 700B comprises a soft limiter portion 810, and a filter portion 812. The soft limiter portion 810 comprises the same components as comprised in the soft limiter 402 of the embodiment of FIG. 6A. The filter portion 812 comprises the capacitor C_{LOAD} (FIG. 8A) that is connected in parallel with the resistor R_{LOAD} and with the diodes D₁ and D₂. The resistor G_{IN} is coupled to an input voltage V_{IN4}. V_{OUT4} is the output voltage of the amplifier 502, and I₄ is a current through the resistor G_{IN}.

The soft limiter portion 810 soft limits a signal that is input to the soft limiter and filter 700B. Simultaneously, the filter portion 812 filters the signal. The soft limiter portion 810 soft limits as follows. When the voltage V_{IN4} is between certain values, both of the diodes D₁ and D₂ are off, and there is a linear relationship between the voltage V_{OUT4} and the current I₄. The linear relationship is provided by

V_{OUT4}=C₄I₄ Equation 8

where C₄ is a constant.

The soft limiter portion 810 soft limits the signal that is input to the soft limiter and filter 700B by limiting the signal between the two values, −V_{BE(ON)} and V_{BE(ON)}. When the voltage V_{IN4} is large enough to turn on the diode D₁, voltage across the diode D₁ is V_{BE(ON)}, and the voltage V_{OUT4} saturates to the value of −V_{BE(ON)}. The diode D₂ is off at this time. When the voltage V_{IN4} is small enough to turn on the diode D₂, the voltage across the diode D₁ is −V_{BE(ON)}, and the voltage V_{OUT4} saturates to the constant value of V_{BE(ON)}. The diode D₁ is off at this time. The relationship between the voltage V_{IN4} and the current I₄ is given by

I₄=G_{IN}V_{IN4} Equation 9

The filter portion 812 simultaneously filters the signal since the resistor R_{LOAD} and the capacitor C_{LOAD} are parallel to the diodes D₁ and D₂. The diodes D₁ and D₂ play a major role in soft limiting the signal, and the capacitor C_{LOAD} and the resistor R_{LOAD} form a frequency-dependent network that filters the signal. Hence, there is simultaneous soft limiting and filtering of the signal that is input to the soft limiter and filter 700B.

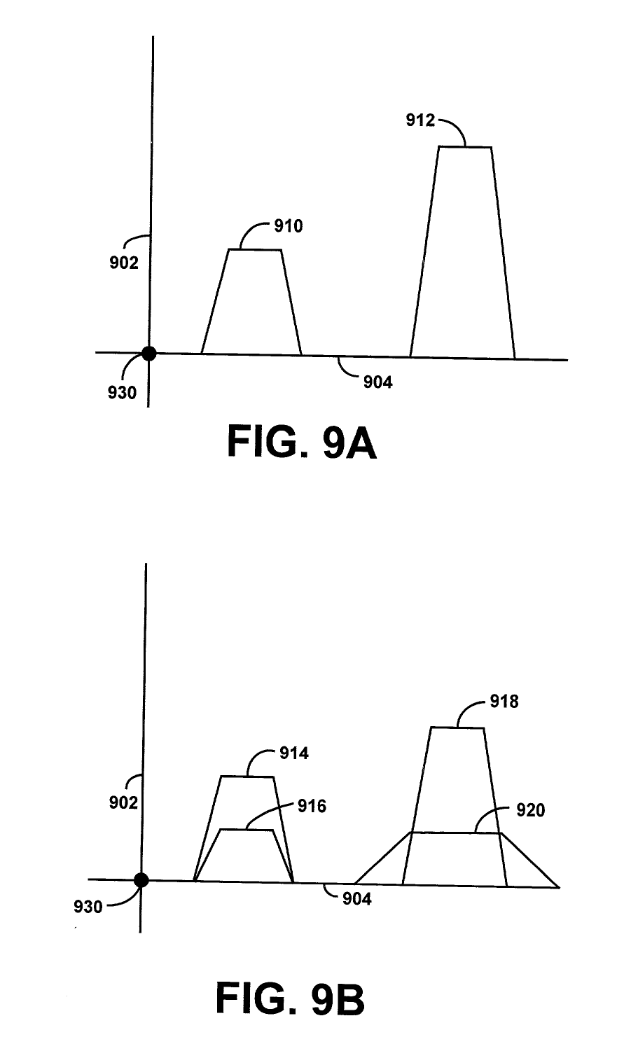

FIG. 9A is a graph of a signal 910 and a blocker 912 that may be received as an input to the soft limiter 402 of FIG. 4 and to the soft limiter portions 802 and 810 of FIGS. 8A and 8B, respectively. Axis 904 is a range of frequencies from zero to infinity. A point 930 represents a frequency of zero. Axis 902 is a range of amplitudes from zero to infinity, where the point 930 represents an amplitude of zero.

FIG. 9B is a graph of a signal 914 and a blocker 918 that may be output from the soft limiter 402 of FIG. 4, and the soft limiter portions 802 and 810 of FIGS. 8A and 8B, respectively. There is in-band intermodulation distortion 916 and intermodulation distortion 920 created by the frequencies of the signal 910 (FIG. 9A) and the blocker 912 (FIG. 9A). Signal-to-distortion ratio is a ratio of the signal 914 to the in-band intermodulation distortion 916. There should be a certain signal-to-distortion ratio at the output of each of the soft limiters 402 (FIG. 4), of the soft limiter portion 802 (FIG. 8A), and of the soft limiter portion 810 (FIG. 8B) for the processor 224 (FIG. 2) to be able to extract data from the digital signal that it receives via the line 228 (FIG. 2). To achieve this certain signal-to-distortion ratio, the amplitude of the blocker 912 (FIG. 9A) should be such that it passes through any of the soft limiter and filter 300 (FIGS. 3 and 4), and the soft limiter and filters 701 and 702 (FIG. 7) without being soft limited. The signal 910, however, can be of any amplitude. For instance, if the amplitude of the signal 910 (FIG. 9A) is approximately equal to the sum of the amplitude of the blocker 912 (FIG. 9A) and 6 dB, the signal-to-distortion ratio will be at least 16 dB and so the processor 224 (FIG. 2) can extract data from the digital signal that it receives via the line 228 (FIG. 2).

As stated above, the receiver 210 (FIG. 2) of the present invention has many advantages over other known receivers. For example, the receiver 210 (FIG. 2) of the present invention is less costly than receivers such as that shown in FIG. 1 because the receiver 210 does not require the amplifier 116 (FIG. 1) with the large range of adjustable gain or the detector 126 (FIG. 1) that measures the strength of a signal that is input to the detector 126 (FIG. 1) to adjust the gain of the amplifier 116. Moreover, there is no blanking time associated with the receiver 210 (FIG. 2) of the present invention because there is no need to change the gain of an amplifier, such as the amplifier 116 (FIG. 1) to protect a filter, such as the filter 118 (FIG. 1).

It should be noted that the above-described embodiments of the present invention, particularly, any “preferred” embodiments, are merely possible examples of implementations of the present invention that have been set forth herein for the purpose of providing a clear understanding of the principles of the invention. As will be understood by those skilled in the art from a reading of the present disclosure, many variations and modifications may be made to the above-described embodiments of the invention without departing from the scope of the invention. All such modifications and variations are within the scope of the present invention.

What is claimed is:

1. A chain that limits and filters a combined signal, the chain comprising:
at least one soft limiter and filter that soft limits and filters the combined signal to output a soft limited and filtered signal.

2. The chain of claim 1, wherein the combined signal comprises a blocker and a non-zero intermediate frequency (IF) signal, the non-zero IF signal having angular modulation.

3. The chain of claim 2, further comprising
a hard limiter for hard limiting the soft limited and filtered signal.

4. The chain of claim 3, wherein the at least one soft limiter and filter comprises:
a soft limiter that soft limits the combined signal to output a soft limited signal; and
a filter that filters the soft limited signal to output the soft limited and filtered signal.

5. The chain of claim 3, wherein the at least one soft limiter and filter comprises:
a soft limiter portion that soft limits the combined signal; and
a filter portion that filters the combined signal.

6. The chain of claim 5, wherein the soft limiter portion first soft limits the combined signal, and then the filter portion filters the combined signal.

7. The chain of claim 5, wherein the soft limiter portion soft limits the combined signal, and the filter portion simultaneously filters the combined signal.

8. The chain of claim 3, wherein the blocker passes through the soft limiter without being soft limited if the combined signal does not comprise the non-zero IF signal.

9. A chain that limits and filters a combined signal, comprising:
at least one soft limiter and filter that soft limits and filters the combined signal to output a soft limited and filtered signal; and
a hard limiter for hard limiting the soft limited and filtered signal.

10. A receiver, comprising:
a chain that receives a combined signal, the chain comprising:
a soft limiter and filter for soft limiting and filtering the combined signal to output a soft limited and filtered signal, and a hard limiter for hard limiting the soft limited and filtered signal to output a limited filtered signal;
an analog-to-digital converter for converting the limited filtered signal to a digital signal; and
a processor for demodulating the digital signal.

11. A method for limiting and filtering a combined signal, comprising:
soft limiting and filtering the combined signal to output a soft limited and filtered signal.

12. The method of claim 1, wherein the combined signal comprises a blocker and a non-zero intermediate frequency (IF) signal, the non-zero IF signal having angular modulation.

13. The method of claim 12, further comprising:
hard limiting the soft limited and filtered signal.

14. The method of claim 13, wherein the step of soft limiting and filtering, comprises:
soft limiting the combined signal to output a soft limited signal; and
filtering the soft limited signal to output the soft limited and filtered signal.

15. The method of claim 14, wherein the soft limiting is done before the filtering.

16. The method of claim 14, wherein the soft limiting takes place simultaneous to the filtering.

17. The method of claim 15, wherein the blocker is not soft limited if the combined signal does not comprise the non-zero IF signal.

18. A method for limiting and filtering a combined signal, comprising:
soft limiting and filtering the combined signal to output a soft limited and filtered signal; and
hard limiting the soft limited and filtered signal.

19. A method for limiting and filtering a combined signal, comprising:
soft limiting and filtering the combined signal to output a soft limited and filtered signal;
hard limiting the soft limited and filtered signal to output a limited filtered signal;
converting the limited filtered signal to a digital signal; and
demodulating the digital signal.

20. A system for limiting and filtering a combined signal, comprising:
means for soft limiting and filtering the combined signal to output a soft limited and filtered signal.

21. The system of claim 20, wherein the combined signal comprises a blocker and a non-zero intermediate frequency (IF) signal, the non-zero IF signal having angular modulation.

22. The system of claim 21, further comprising:
means for hard limiting the soft limited and filtered signal.

23. The system of claim 22, wherein the means for soft limiting and filtering, comprises:
means for soft limiting the combined signal to output a soft limited signal; and
means for filtering the soft limited signal to output the soft limited and filtered signal.

24. The system of claim 23, wherein the means for soft limiting soft limits before the filtering.

25. The system of claim 23, wherein the means for soft limiting soft limits simultaneous to the filtering.

26. A system for limiting and filtering a combined signal, comprising:
means for soft limiting and filtering the combined signal to output a soft limited and filtered signal;
means for hard limiting the soft limited and filtered signal to output a limited filtered signal;
means for converting the limited filtered signal to a digital signal; and
means for demodulating the digital signal.
